(19) United States
(12) Patent Application Publication
(10) Pub. No.: US 2026/0214831 A1
(43) Pub. Date: Jul. 23, 2026

(54) SERVER RACK WITH BUSBAR CLIP CONNECTOR FOR STRAY CURRENT

(71) Applicant: Dell Products L.P., Round Rock, TX (US)

(72) Inventors: Douglas Evan Messick, Austin, TX (US); John Erven Jenne, Georgetown, TX (US)

(21) Appl. No.: 19/032,942

(22) Filed: Jan. 21, 2025

(51) Int. Cl. H05K 7/14

(52) U.S. Cl. CPC H05K 7/1492

(57) ABSTRACT

A server rack, including a plurality of rack units; a computing tray positioned within a particular rack unit of the plurality of rack units, the computing tray configured to house a computing chassis and computing components; a busbar; and a busbar clip removably coupled to the busbar, the busbar clip i) providing a first connection from the computing components to a busbar ground and ii) providing a second connection from the computing chassis to the busbar ground, the second connection isolated from the first connection, wherein the second connection is configured to provide a low impedance connection for rack return current to the busbar.

### BACKGROUND

### Field of the Disclosure

The disclosure relates generally to a server rack, and in particular, a server rack with a busbar clip connector for stray current.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Server rack return current is the electrical current that flows back to the power source after passing through the server components. When this current inadvertently travels through the metal frame of the rack, it can create several problems. One major issue is electromagnetic interference (EMI), which can disrupt the performance of nearby electronic devices and degrade the quality of data transmission. Additionally, the flow of return current through the metal frame can lead to overheating, posing a risk of damage to the server components and potentially causing system failure.

### SUMMARY

Innovative aspects of the subject matter described in this specification may be embodied in a server rack, including: a plurality of rack units; a computing tray positioned within a particular rack unit of the plurality of rack units, the computing tray configured to house a computing chassis and computing components; a busbar; and a busbar clip removably coupled to the busbar, the busbar clip i) providing a first connection from the computing components to a busbar ground and ii) providing a second connection from the computing chassis to the busbar ground, the second connection isolated from the first connection, wherein the second connection is configured to provide a low impedance connection for rack return current to the busbar.

Other embodiments of these aspects include corresponding systems and apparatus.

These and other embodiments may each optionally include one or more of the following features. For instance, the busbar clip includes i) a first set of fingers that provide the first connection from the computing components to the busbar ground and ii) a second set of fingers that provide the second connection from the computing chassis to the busbar ground, the second connection isolated from the first connection. The first connection is configured to provide a ground connection for the computing components. The computing components include a printed circuit board (PCB), wherein the first set of fingers provide the first connection from the PCB to the busbar ground. The first set of fingers of the busbar clip are isolated from the second set of fingers of the busbar clip. The second connection is configured to provide the low impedance connection for rack return current to the busbar while bypassing the computing components. The second connection is a ground connection to the busbar. The second connection is electrically isolated from the first connection. The computing components are electrically isolated from the computing chassis.

Particular implementations of the subject matter described in this specification can be implemented so as to realize one or more of the following advantages. For example, the busbar clip can enable stray current to be mitigated without significant cost, complexity, or major electrical or mechanical design changes to the server rack, the server, computing chassis, busbars, or busbar clips.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a front view of a server rack.

FIG. 3 illustrates a top-down view of a power shelf.

FIG. 4 illustrates a simplified view of the power shelf, including a first connection and a second connection.

FIG. 5 illustrates a perspective view of a busbar clip.

### DESCRIPTION OF PARTICULAR EMBODIMENTS

This disclosure discusses a server rack with a busbar clip connector for stray current. In short, the busbar clip can provide an additional isolated ground connection specifically for rack return currents of the rack. The busbar clip can include additional grounded fingers to enable rack return current to flow from a computing chassis to the busbar. Thus, rack stray current traveling through the rack will flow into the chassis of the computing tray and directly into the busbar via separate fingers of the busbar clip to completely bypass other electronic components of the computing tray. That is, the busbar clip and the separate fingers provide an additional isolated ground path to mitigate rack return current from the rack and chassis ground to busbar ground, described further herein.

Specifically, this disclosure discusses a server rack, including a plurality of rack units; a computing tray positioned within a particular rack unit of the plurality of rack units, the computing tray configured to house a computing chassis and computing components; a busbar; and a busbar clip removably coupled to the busbar, the busbar clip i) providing a first connection from the computing components to a busbar ground and ii) providing a second connection from the computing chassis to the busbar ground, the second connection isolated from the first connection, wherein the second connection is configured to provide a low impedance connection for rack return current to the busbar.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

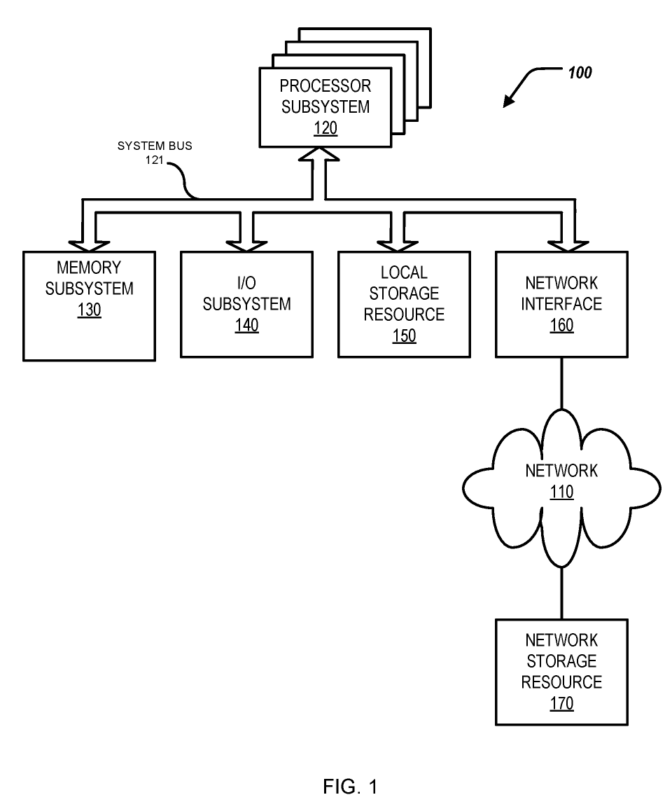

Particular embodiments are best understood by reference to FIGS. 1-5 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system 100). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

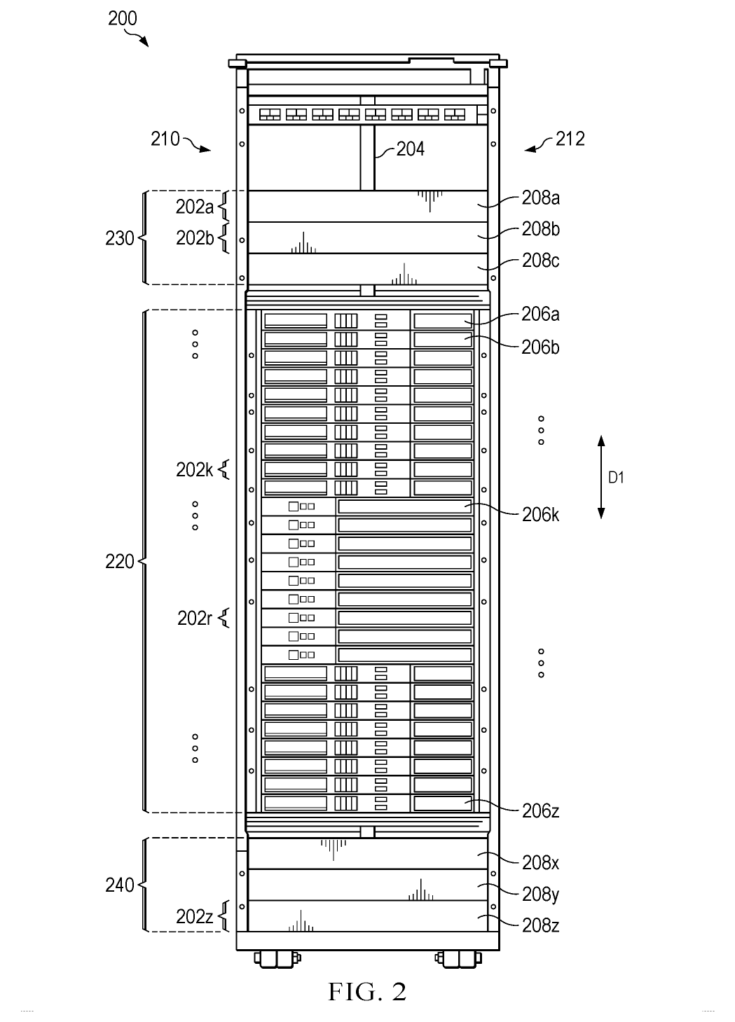

Turning to FIG. 2, FIG. 2 illustrates a server rack 200. The server rack 200 can include rack units 202a-202z (collectively referred to as rack units 202), a busbar 204, servers 206a-206z (collectively referred to as servers 206), and power shelves 208a-208z (collectively referred to as power shelves 208). In some examples, the servers 206 are similar to, or include, the information handling system 100 of FIG. 1.

The server rack 200 includes a first side 210 and a second side 212. The first side 210 is positioned opposite to the second side 212. The rack units 202 can extend between the first side 210 and the second side 212 of the server rack 200. The server rack 200 can include any number of rack units 202 depending on the application desired.

The servers 206 can be positioned within a respective rack unit 202. Specifically, the servers 206 can be positioned within a respective rack unit 202 of a first subset 220 of the rack units 202. In other words, the servers 206 can be coupled to respective rack units 202 of the first subset 220 of the rack units 202. The server rack 200 can include any number of servers 206 depending on application desired.

The power shelves 208 can be positioned within a respective rack unit 202. Specifically, the power shelves 208a-208c can be positioned within a respective rack unit 202 of a second subset 230 of the rack units 202. In other words, the power shelves 208a-208c can be coupled to respective rack units 202 of the second subset 230 of the rack units 202. Furthermore, the power shelves 208x-208z can be positioned within a respective rack unit 202 of a third subset 240 of the rack units 202. In other words, the power shelves 208x-208z can be coupled to respective rack units 202 of the third subset 240 of the rack units 202. The server rack 200 can include any number of power shelves 208 depending on the application desired.

The busbar 204 spans at least a portion of the server rack 200 along the direction D1. In some examples, the busbar 204 is electrically coupled to one or more of the rack units 202. In some examples, the busbar 204 is electrically couped to each of the rack units 202. The busbar 204 is configured to provide power from one or more of the power shelves 208 to one or more of the servers 206.

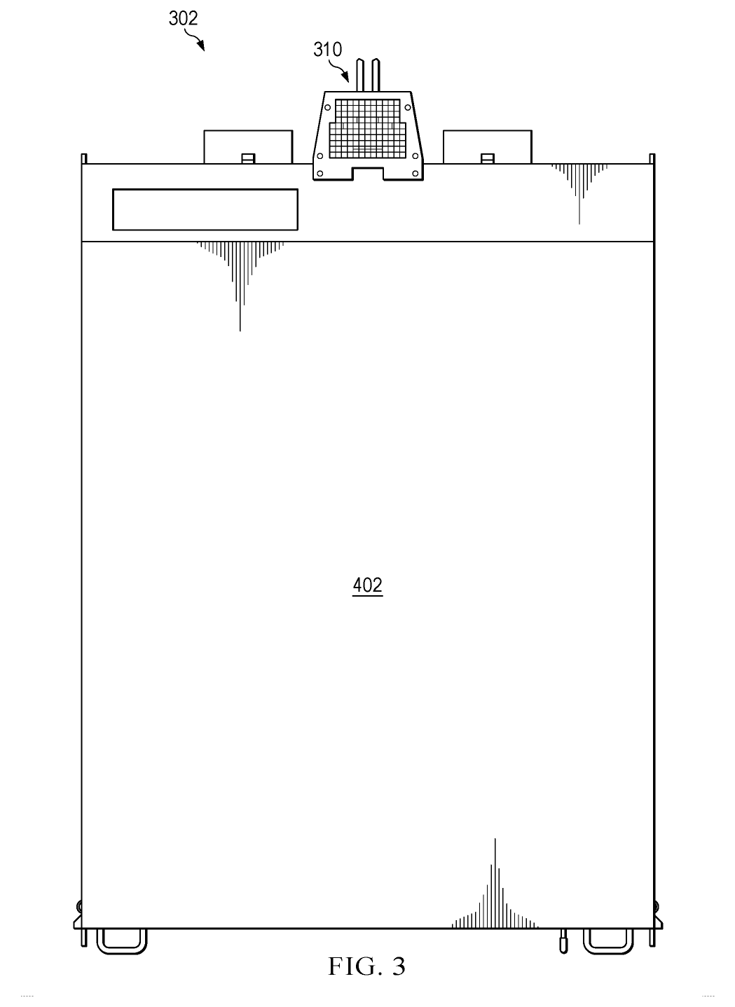

FIG. 3 illustrates a top-down view of a computing tray 302. The computing tray 302 can include the server 206, the power shelf 208, or any computing tray that can be utilized at the server rack 200. For example, the computing tray 302 can include any of the power shelf 208, the server 206, computing tray, switch trays, and any other devices that connects to the rack units 202 and the busbar 204. The computing tray 302 can be positioned within a particular rack unit 202 of the rack units 202. The computing tray 302 can further include a busbar clip 310.

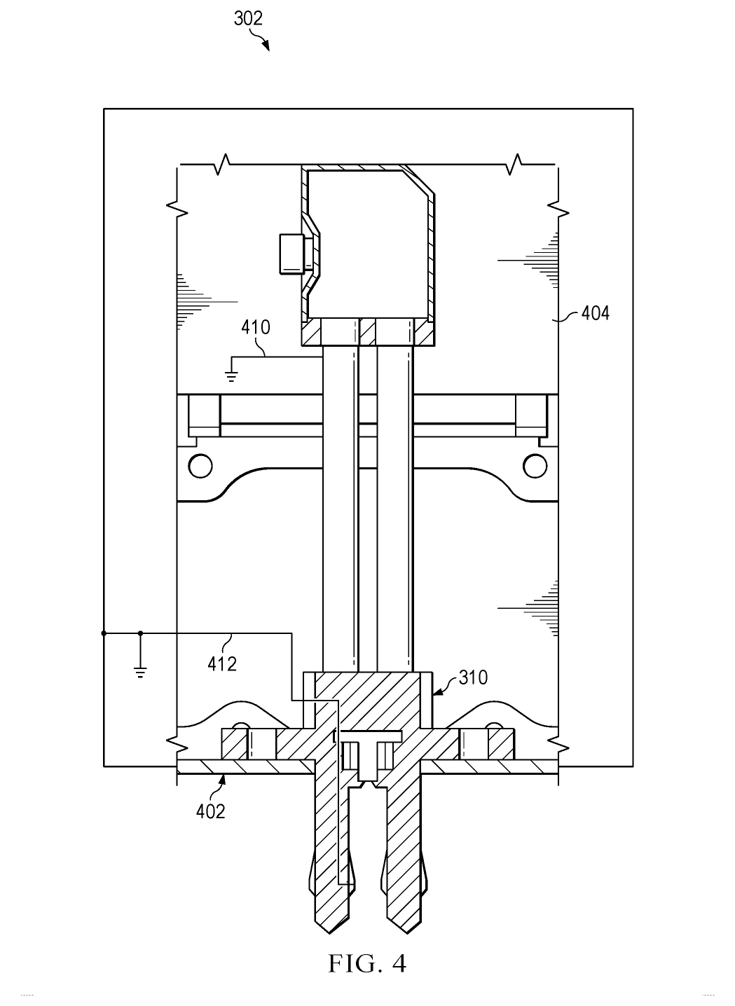

FIG. 4 illustrates a simplified top-down view of the computing tray 302. The computing tray 302 can be configured to house, or include, a computing chassis 402 and computing components. In some examples, the computing components can include a printed circuit board (PCB) 404. In some examples, the computing tray 302 is a power shelf 208 positioned with the particular rack unit 202, and includes a power shelf chassis and power shelf components, such as the PCB 404. The computing components, such as the PCB 404, are electrically isolated from the computing chassis 402.

In short, the busbar clip 310 can provide an additional isolated ground connection specifically for rack return currents of the rack 200. The busbar clip 310 can include additional grounded fingers to enable rack return current to flow from the computing chassis 402 to the busbar 204. Thus, rack stray current traveling through the rack 200 will flow into the chassis 402 of the computing tray 302 and directly into the busbar 204 via separate fingers of the busbar clip 310 to completely bypass other electronic components of the computing tray 302. That is, the busbar clip 310 and the separate fingers provide an additional isolated ground path to mitigate rack return current from the rack 200 and chassis ground to busbar ground, described further herein.

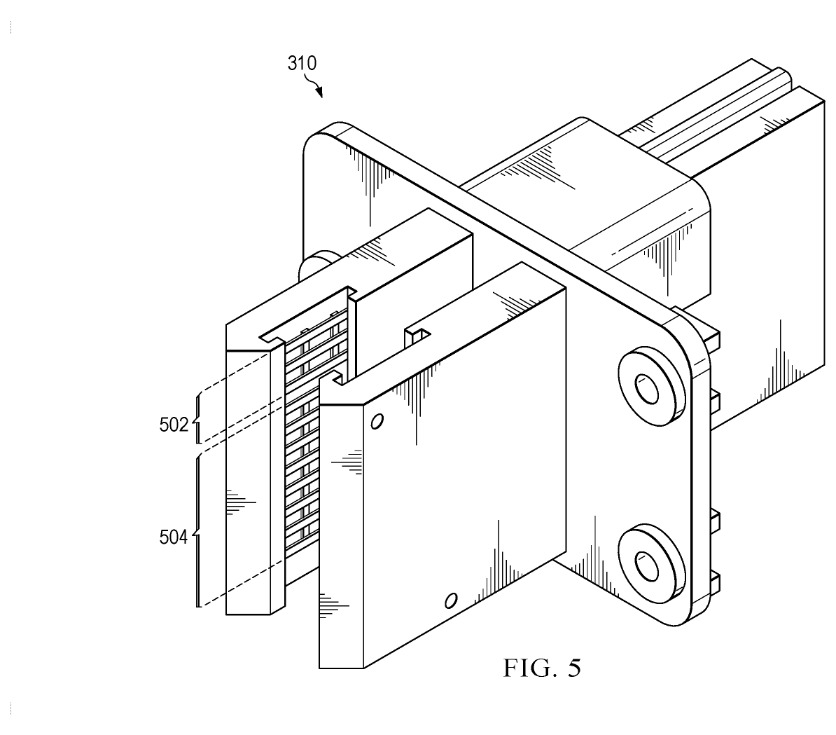

FIG. 5 illustrates a perspective view of the busbar clip 310. Referring to FIGS. 2-5, the busbar clip 310 can be removably coupled to the busbar 204. The busbar clip 310 can provide a first connection 410 from the computing components to a busbar ground. For example, the busbar clip 310 can provide the first connection 410 from the PCB 404 to the busbar ground. That is, the first connection 410 is a ground connection to the busbar 204. The busbar clip 310 can further provide a second connection 412 from the computing chassis 402 to the busbar ground. That is, the second connection 412 is a ground connection to the busbar 204.

The busbar clip 310 can include a first set of fingers 502 and a second set of fingers 504. The first set of fingers 502 can provide the first connection 410 from the computing components to the busbar ground. For example, when the computing components include the PCB 404, the first set of fingers 502 provide the first connection 410 from the PCB 404 to the busbar ground. The first set of fingers 502 route the first connection to the busbar ground. The second set of fingers 504 can provide the second connection 412 from the computing chassis 402 to the busbar ground. The second set of fingers 504 route the second connection to the busbar ground. In some examples, when the computing tray 302 includes the power shelf 208, the first set of fingers 502 provide the first connection 410 from the power shelf components (e.g., the PCB 404) to the busbar ground; and the second set of fingers 504 provide the second connection 412 from the power shelf chassis to the busbar ground.

The first connection 410 is isolated from the second connection 412. In particular, the first connection 410 is electrically isolated from the second connection 412. That is, the first set of fingers 502 are isolated from the second set of fingers 504; and in particular, the first set of fingers 502 are electrically isolated from the second set of fingers 504.

To that end, the first connection 410 is configured to provide a ground connection for the computing components. For example, the first connection 410 is configured to provide a ground connection for the PCB 404. When the computing chassis 402 includes the power shelf 208, the first connection 410 is configured to provide a ground connection for the power shelf components.

Further, the second connection 412 is configured to provide a low impedance connection for rack return current to the busbar 204. That is, the second connection 412 provides a low impedance path from the chassis 402 to the busbar ground that is isolated from the ground of the computing components (the first connection 410). That is, the second connection 412 is configured to provide the low impedance connection for rack return current to the busbar 204 while bypassing the computing components – e.g., the PCB 404. That is, the second connection 412 is configured to provide the low impedance connection for rack return current to the busbar 204 while bypassing the computing components, such as all electrical AC to DC power conversion and all electrical components. The second connection 412 is electrically isolated from the first connection 410 such that the second connection 412 can provide the low impedance connection for rack return current to the busbar 204 while bypassing the computing components.

Thus, rack stray current traveling through the rack 200 will flow into the chassis 402 of the computing tray 302 and directly into the busbar 204 via the busbar clip 310, the second connection 412, and the second set of fingers 504 to completely bypass other electronical components of the computing tray 302. That is, the busbar clip 310, the second connection 412, and the second set of fingers 504 provide an additional isolated ground path to mitigate rack return current from the rack 200 and chassis ground to busbar ground.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. A server rack, including:
a plurality of rack units;
a computing tray positioned within a particular rack unit of the plurality of rack units, the computing tray configured to house a computing chassis and computing components;
a busbar; and
a busbar clip removably coupled to the busbar, the busbar clip i) providing a first connection from the computing components to a busbar ground and ii) providing a second connection from the computing chassis to the busbar ground, the second connection isolated from the first connection,
wherein the second connection is configured to provide a low impedance connection for rack return current to the busbar.

2. The server rack of claim 1, wherein the busbar clip includes i) a first set of fingers that provide the first connection from the computing components to the busbar ground and ii) a second set of fingers that provide the second connection from the computing chassis to the busbar ground, the second connection isolated from the first connection.

3. The server rack of claim 1, wherein the first connection is configured to provide a ground connection for the computing components.

4. The server rack of claim 2, wherein the computing components include a printed circuit board (PCB), wherein the first set of fingers provide the first connection from the PCB to the busbar ground.

5. The server rack of claim 2, wherein the first set of fingers of the busbar clip are isolated from the second set of fingers of the busbar clip.

6. The server rack of claim 1, wherein the second connection is configured to provide the low impedance connection for rack return current to the busbar while bypassing the computing components.

7. The server rack of claim 1, wherein the second connection is a ground connection to the busbar.

8. The server rack of claim 1, wherein the second connection is electrically isolated from the first connection.

9. The server rack of claim 1, wherein the computing components are electrically isolated from the computing chassis.

10. A server rack, including:
a plurality of rack units;
a power shelf positioned within a particular rack unit of the plurality of rack units, the power shelf configured to house a power shelf chassis and power shelf components;
a busbar; and
a busbar clip removably coupled to the busbar, the busbar clip including i) a first set of fingers providing a first connection from the power shelf components to a busbar ground and ii) a second set of fingers providing a second connection from the power shelf chassis to the busbar ground, the second connection isolated from the first connection,
wherein the first connection is configured to provide a ground connection for the power shelf components, and
wherein the second connection is configured to provide a low impedance connection for rack return current to the busbar.

11. The server rack of claim 10, wherein the power shelf components include a printed circuit board (PCB), wherein the first set of fingers provide the first connection from the PCB to the busbar ground.

12. The server rack of claim 10, wherein the first set of fingers of the busbar clip are isolated from the second set of fingers of the busbar clip.

13. The server rack of claim 10, wherein the second connection is configured to provide the low impedance connection for rack return current to the busbar while bypassing the power shelf.

14. The server rack of claim 10, wherein the second connection is a ground connection to the busbar.

15. The server rack of claim 10, wherein the second connection is electrically isolated from the first connection.

16. The server rack of claim 10, wherein the power shelf components are electrically isolated from the power shelf chassis.

17. A computing tray, including:
a computing chassis;
computing components; and
a busbar clip removably coupled to a busbar, the busbar clip including i) a first set of fingers providing a first connection from the computing components to a busbar ground and ii) a second set of fingers providing a second connection from the computing chassis to the busbar ground, the second connection isolated from the first connection,
wherein the second connection is configured to provide a low impedance connection for rack return current to the busbar.

18. The computing chassis of claim 17, wherein the first connection is configured to provide a ground connection for the computing components.

19. The computing chassis of claim 18, wherein the computing components include a printed circuit board (PCB), wherein the first set of fingers provide the first connection from the PCB to the busbar ground.

20. The computing chassis of claim 18, wherein the first set of fingers of the busbar clip are isolated from the second set of fingers of the busbar clip.
